(19) United States
(12) Patent Application Publication
(10) Pub. No.: US 2007/0169687 A1
(43) Pub. Date: Jul. 26, 2007

(54) Silicon carbide formation by alternating pulses

(75) Inventor: Olof Claes Erik Kordina, Pittsburgh, PA (US)

Correspondence Address: SCHNADER HARRISON SEGAL & LEWIS, LLP, 1600 MARKET STREET, SUITE 3600, PHILADELPHIA, PA, 19103, US

(73) Assignee: CARACAL, INC., FORD CITY, PA (US)

(21) Appl. No.: 11/341,357

(22) Filed: Jan. 26, 2006

(51) Int. Cl. C30B 23/00; C30B 25/00; C30B 28/12

(52) U.S. Cl. 117/88; 117/224; 117/104; 117/105

(57) ABSTRACT

A method of forming silicon carbide wherein silicon and carbon precursors are successively pulsed into a reactor in the gas phase. The precursors react to form silicon carbide before reaching the growth surface. A precursor will be preheated in the reaction chamber before reacting with the other precursor. The formed silicon carbide sublime then condenses on a growth surface.

### FIELD OF THE INVENTION

The invention relates to crystal growth, and more particularly to silicon carbide crystal growth.

### BACKGROUND OF THE INVENTION

Silicon carbide (SiC) is a semiconductor material with properties highly suitable for high power, high frequency, and high temperature applications. Many applications require a very high quality SiC crystal to minimize device defects and failures. Such high quality silicon carbide is difficult to produce in an efficient manner. Technical obstacles have remained that have inhibited the widespread use of silicon carbide. Reduction in defects in an economical manner must be achieved to realize the full potential of silicon carbide in the electronics industry.

Low cost can best be achieved by increasing the substrate size, increasing throughput, improving yields, and reducing the cost of the consumables used in the processes. Micropipes and other structural imperfections need to be brought down to optimize yields and performance of the devices. Though great strides have been made in terms of reduction of micropipe densities there is still need for a low cost, reliable process yielding substrates of high quality with low densities of structural defects.

The standard way of growing SiC is by seeded sublimation growth. A graphite crucible is filled with SiC powder and a SiC single crystal seed is attached to the lid of the crucible, which is then sealed. The system is heated to temperatures above 2000° C. where SiC sublimes. Temperatures must be quite high to make sure the SiC powder sublimes appreciably. If a thermal gradient is applied such that the seed is colder than the source material, transport will take place from the source to the seed. If the pressure is lowered to a few torr, the material transport is enhanced. Unfortunately, the method has some drawbacks. Due to the thermal gradients, difficulties in controlling the stoichiometry of the sublimed species, and the container material which typically disintegrates in the harsh environment the quality of the crystal is very hard to control.

Micropipe density is significant. Purity is also often a problem. Due to the way the thermodynamics work for the sublimation, the growth is generally rich in silicon (Si) at the beginning, with diminishing amount of Si at the end of the growth. This has severe implications on the yield of semi-insulating wafers since the material will be n-type at the start of the growth and p-type at the end. The length of the grown crystals, commonly called boules, is also limited to the amount of silicon carbide source material in the system.

Gas fed techniques have been developed, which introduce precursors into the reactor by flowing them into the reactor in the gas phase, instead of using powders as is done in seeded sublimation. A description of different gas fed techniques is provided so advantages of embodiments of the present invention will be appreciated.

High Temperature Chemical Vapor Deposition (HTCVD) can also be used to produce silicon carbide crystals. Gases carrying the silicon and carbon needed for the growth replace powder source materials. The HTCVD apparatus generally consists of three separate zones: An entrance zone, a sublimation zone, and a growth (or condensation) zone. The gases used are mainly silane, ethylene, and a low flow of a helium carrier. The process can work without additions of a hydrocarbon in which case the carbon is supplied through a reaction between the hot silicon vapor and the graphite walls.

In the entrance zone, the silane and ethylene decompose and form SiₓC_{y} clusters on account of the high concentration of the precursor gases. The formed micro-particles of SiₓC_{y} will move into the hot chamber or the sublimation zone with the aid of the inert helium carrier gas. Once in the sublimation zone, the micro-particles will sublime to form Si, Si₂C, and SiC₂ as in the case of seeded sublimation growth. A thermal gradient is applied so that the sublimed species will condense on the seed, as is the case of seeded sublimation growth.

The growth rate is influenced by the amount of input precursors, however, too high a concentration will give rise to very large cluster sizes that are formed in the injector, which will be difficult to sublime in the sublimation zone.

The HTCVD technique is inherently unsuitable for the growth of large diameter wafers at high growth rates. The material input per unit time will need to be four times larger for a 4-inch wafer as compared to a 2-inch wafer for the same growth rate. Unfortunately, the cluster size will increase dramatically, making it difficult to sublime the particles.

Material properties of HTCVD grown silicon carbide are usually much better than that of the sublimation grown crystals, however, the defect density could still use improvement, growth rates are low (<1 mm/hr), and temperatures are high, which stresses the crucible and insulation materials making the system drift.

Another method of forming silicon carbide is by Atomic Layer Deposition (ALD). Pursuant to ALD silicon carbide is formed by successively pulsing a silicon precursor and a carbon precursor into a reaction chamber where each component is allowed to react separately on a growth surface. Single atomic layers are formed for each pulse. The principle of the growth technique is that the growth surface will not accept more than a single layer. Intermixing of the successive reactants is avoided before reaching the growth surface. Silicon carbide sometimes forms prior to the precursors reacting with the growth surface, which causes crystal defects when using current ALD growth processes. Steps are taken to eliminate any of the pre-formed silicon carbide from contributing to the silicon carbide crystal growth. This includes introducing the carbon precursor into a pre-reaction chamber after the silicon precursor has been allowed to react with the growth surface to chemically deplete any residual silicon precursor. The process is repeated for any remaining silicon precursor after the silicon has been allowed to react with the growth surface. The precursors react with one another to form a solid product, which is considered waste and is removed from, or allowed to settle in, the pre-reaction chamber. In this manner the reaction chamber will only contain one precursor at a time during the actual crystal growth. This method requires sacrificing material, thereby increasing the time and cost of carrying out the process.

Another technique used to form silicon carbide is Phase Controlled Sublimation (PCS), the subject of the present inventor's U.S. patent application Ser. No. 10/426,200. PCS was developed to make the particle unit that is to sublime as small as possible. This enables a reduction in temperature, thermal gradient, and an increase in pressure while maintaining or exceeding the growth rate and quality of the crystal. To reduce the particle size the carbon source flow and the silane source flow enter the reactor simultaneously but remain spatially separated so they meet at the sublimation zone, which is the hottest part of the reactor.

As in the HTCVD, the silane will form droplets of Si when it decomposes in the injector, however in the absence of carbon these droplets will be comparatively easily vaporized when they reach the hotter zone inside the crucible. Thus, when the silicon flow meets the carbon flow the particles are small and there is a reduced possibility to form larger particles. Thus, the SiₓC_{y} particles formed will be small and hence easy to sublime or they will directly form the SiC2 or Si2C that deposits on the substrate.

The main obstacle is the formation of pyrolytic graphite in the carbon injector which occurs even with a hydrogen carrier if the concentration of the hydrocarbon is high.

A variation of the PCS technique is Halide Vapor Phase Epitaxy (HVPE). In HVPE silicon tetrachloride (tetra) is transported together with an argon (Ar) carrier in the outer tube of a coaxial injector. The Ar carrier helps to insulate the inner tube where the hydrocarbon flows which is ethylene or methane. The hydrocarbon is transported in a hydrogen carrier. In the hot zone the gases mix and the tetra decomposes and SiC is deposited on the seed. Low or no thermal gradients are needed as there is no or minimal sublimation ongoing. The drawback to the HVPE technique is that a high flux of hydrogen in combination with the chlorine causes an undesirable etching of the SiC surface.

Accordingly, there is a need for an improved silicon carbide growth method to produce high quality crystals in a cost effective manner.

### SUMMARY OF THE INVENTION

Embodiments of the invention include a method of forming silicon carbide wherein a silicon precursor and carbon precursor enter the reaction chamber in gas phase at different times. This is accomplished by successively pulsing the precursors into the reactor, either with or without a time gap or purge step in between. The silicon and carbon are encouraged to react before reaching the growth surface. A precursor will be preheated in the reaction chamber before reacting with the other precursor. Substantially all of at least one precursor is reacted in the gas phase to form silicon carbide, which is then sublimed. Substantially all of the sublimed silicon carbide then condenses on a growth surface to form a silicon carbide crystal.

### DESCRIPTION OF DRAWINGS

The invention is best understood from the following detailed description when read with the accompanying drawings.

FIG. 1 depicts a valve apparatus according to an illustrative embodiment of the invention.

FIG. 2 depicts a cross section of a valve apparatus according to an illustrative embodiment of the invention.

FIG. 3 depicts another cross sectional view of a valve apparatus according to an illustrative embodiment of the invention.

FIG. 4 depicts a rotating portion of a valve apparatus according to an illustrative embodiment of the invention.

FIGS. 5A-B depict a cross sectional view of a portion of a valve apparatus showing use of a trash line according to an illustrative embodiment of the invention.

FIG. 6 depicts a crucible with an injector according to an illustrative embodiment of the invention.

FIG. 7 depicts a nozzle according to an illustrative embodiment of the invention.

FIG. 8 depicts a valve timing sequence according to an illustrative embodiment of the invention.

### DETAILED DESCRIPTION OF THE INVENTION

Embodiments of the present invention provide a novel method of forming silicon carbide, and depending on the specific conditions used, may more cost effectively provide a high quality crystal than conventional growth methods. The method can also be applied to formation of other compounds, such as group III nitrides and alloys thereof, but is particularly suitable to the formation of silicon carbide. As such, the invention will be described by illustrative embodiments related to silicon carbide.

To the inventor's knowledge, pulsing of silicon and carbon precursors into a reaction chamber to form silicon carbide has always been performed in a manner to reduce or eliminate silicon carbide formation prior to the reactants reaching the growth surface, such as in ALD. Surprisingly, the inventor has found that reacting the pulses before reaching the growth surface can be advantageous if it is controlled in a manner to create low-defect crystals. In addition, the inventor's techniques are not limited to single atomic layer formation as is ALD.

According to embodiments of the invention, silicon carbide is formed by successively pulsing silicon and carbon precursors into a reaction chamber. Successive pulsing may be accomplished by using a rotating valve. In the preferred embodiment of the invention, the injection of precursors alternates, although it is also possible to inject one precursor followed by two or more injections of the other precursor. Due to the issues with pyrolytic graphite it is advantageous to inject the carbon in some manner rather than have it simply flow.

Once a precursor enters the reaction chamber it is preheated before the next injection of a precursor. This can enhance the reactivity of the precursors.

In a preferred embodiment of the invention, substantially all of at least one precursor is reacted with the other precursor in the gas phase to form silicon carbide prior to reaching a growth surface. (This differs from ADL in that each precursor in ADL reacts separately with the growth surface and any prior formation of SiC before those reactions is discouraged.) The formed silicon carbide is then sublimed, and preferably substantially all of the formed silicon carbide is condensed on a growth surface.

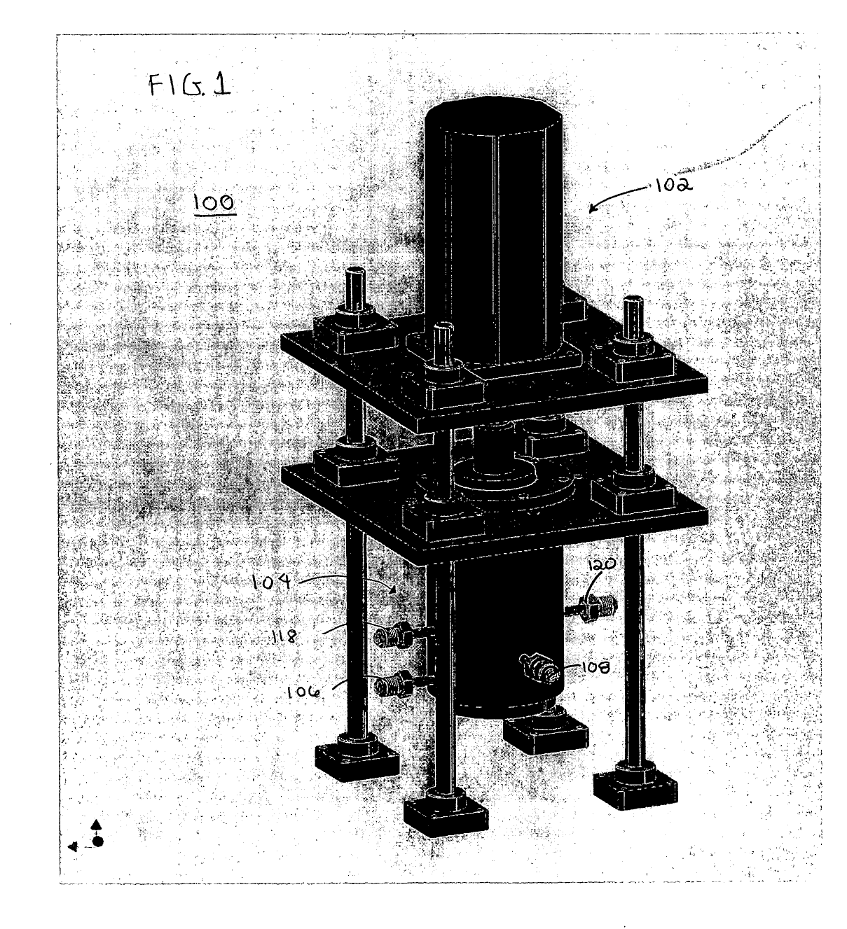

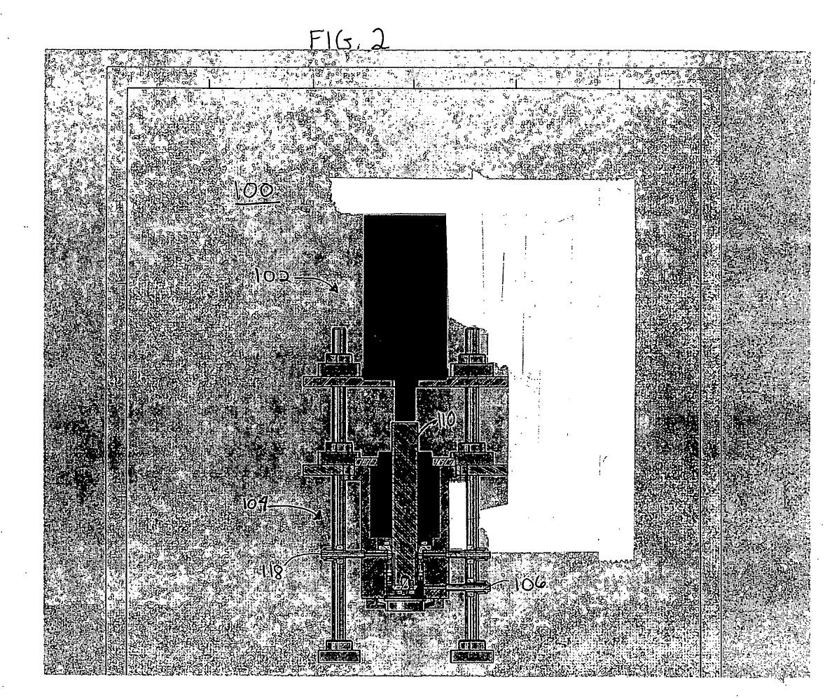

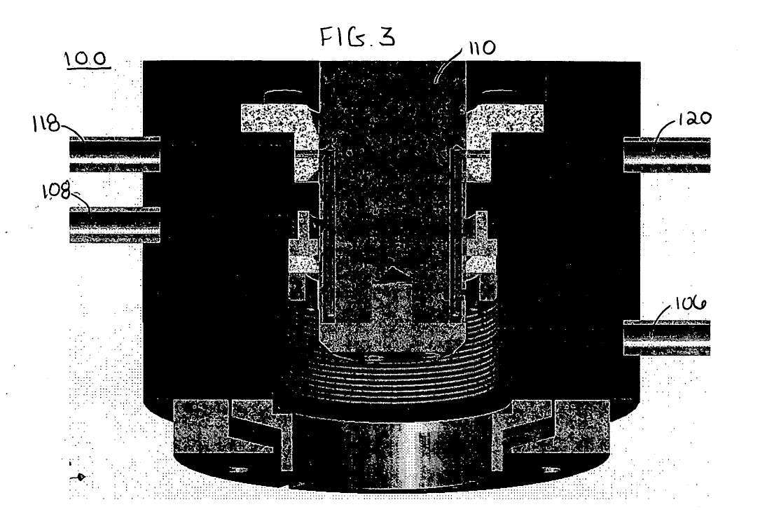

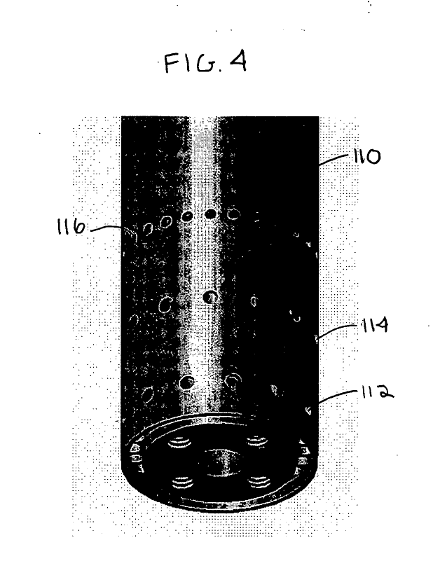

The silicon precursor and carbon precursor may react before reaching the hot zone or in the hot zone. The hot zone is the hottest part of the reaction chamber. Preferably the materials mix in the hot zone. If the reactants mix past the hot zone carbon will not be consumed to the extent it would otherwise, which negatively affects crystal growth. The silicon and carbon precursors will react in an area of the chamber, whether the hottest part or not, having a temperature in the range of about 1000° C. to about 2500° C. Other illustrative temperature ranges in which the silicon and carbon precursors will react include about 1800° C. to about 2400° C. and about 2000° C. to about 2200° C. Generally it is desirable for the temperature of the hottest part of the sublimation zone to be in excess of the temperature required to sublime essentially all supplied silicon carbide. Optimum temperature will depend, at least in part, on the type of crystal being formed. FIGS. 1-3 depict a valve apparatus 100 according to an illustrative embodiment of the invention. FIG. 1 is an exterior view of the apparatus showing a motor 102 and a rotating valve portion 104 driven by motor 102. Cross-sectional views are shown in FIGS. 2 and 3 providing detail of the valve configuration. The valve apparatus will be described as it relates to silicon carbide formation, although it can be applied to other types of crystal formation. A silicon source is input to the apparatus through line 106. A carbon source enters the apparatus through line 108. The silicon and carbon sources are transported through a rotating cylinder 110. Additional detail of cylinder 110 is provided in. FIG. 4. Cylinder 110 has a series of entry holes 112 that are in fluid connection with silicon line 106 and will be filled with a silicon carrying gas. Another series of entry holes 114 in cylinder 110 are in fluid connection with carbon line 108 and will be filled with a carbon carrying gas. Carbon entry holes 114 are staggered with respect to silicon entry holes 112. A row of exit holes 116 is positioned to periodically align with a process line 118 through which gases can enter a process reactor. The number of exit holes 116 equals the sum of silicon entry holes 116 and carbon entry holes 114. As cylinder 110 rotates the silicon source exits alternately with the carbon source because of the staggered arrangement of entry holes 112 and 114. At any time in which a silicon entry hole or a carbon entry hole aligns with an exit hole the carbon or silicon source will be allowed to enter the process reactor.

Preferably there are an odd number of entry holes in connection with the silicon source and an odd number of entry holes in connection with the carbon source. In this example there are 13 entry holes in the series connected with the silicon line 106, and 13 entry holes in the series connected with the carbon line 108. In this case there will be 26 exit holes. This configuration produces alternating pulses of silicon and carbon source gases. The holes can also be arranged to allow other sequences of gas pulsing. For example, if it is desirable to have two carbon pulses for each silicon pulse, there will be twice as many carbon entry holes as silicon entry holes and they will be staggered so two carbon entry holes are between consecutive silicon entry holes.

FIGS. 1 and 3 also show a trash line 120 through which gases can be released from the valve apparatus. Trash line 120 can be used to reduce pressure build up in the silicon and carbon input lines. Input of the carbon and silicon sources into valve apparatus 100 alternates. While the silicon line is closed, pressure builds up in the line so that when it is opened again there will be a burst of gas emitted from the line. As an example, if a flow of 1 SLM through a 3 m long ¼″ gas tube with an internal diameter of approximately 3 mm is provided, the volume of this tube is 21.2 ml. 1 SLM is 16.7 ml/s, thus the tube will be filled 1.27 times every second, or in 100 ms the pressure in the tube will increase by 0.127 atm (approximately 100 torr). If the pressure in the line is about 300 torr to begin with an increase of 100 torr is very significant. The excess pressure will cause the gas to burst into the chamber in an exponential fashion.

[image]

With a faster switching time the pressure buildup is much smaller so the initial burst of gas will not be so significant and the flow will be smoother. But if the steady state pressure (300 torr in this example) is not reached at the time the valve is closed again, the pressure will build up to some quasi steady state.

Instead of, or in addition to, offsetting bursts by faster switching, the gas flow can be directed into a pressure balanced trash line. One of the valves or entries to either the chamber (process reactor) or trash line is open when the other is closed. Ideally there is no time delay between the one closing and the other opening, however, this is usually very difficult to achieve.

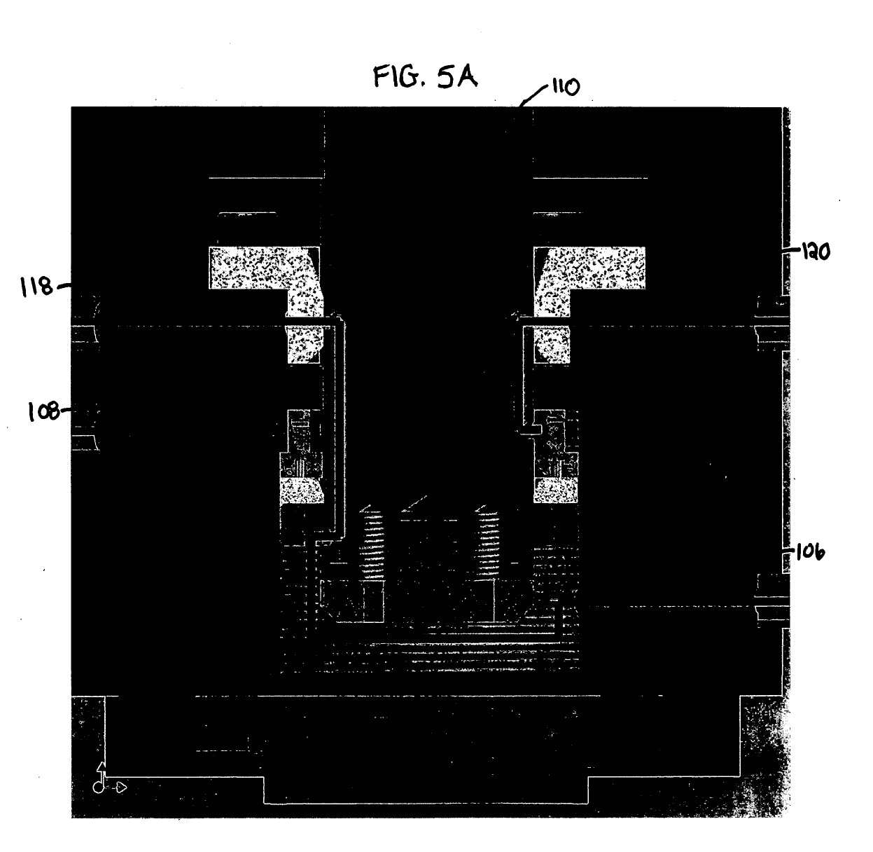

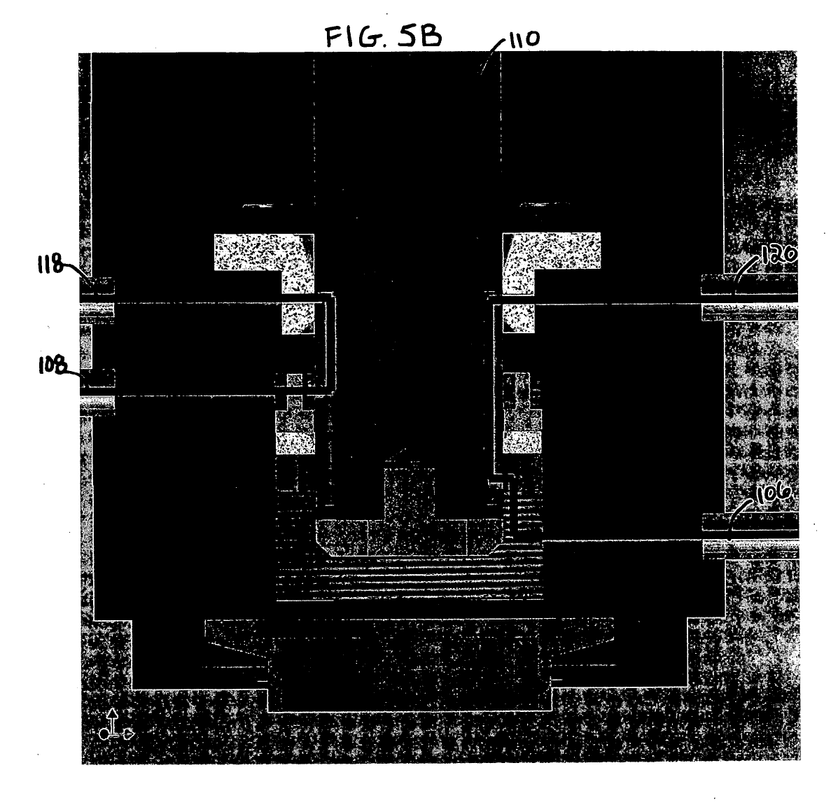

FIGS. 5A-B depict a cross section of a valve apparatus according to an illustrative embodiment of the invention in which an exemplary gas exiting operation can be seen. In this embodiment, gas can exit cylinder 110 from process line 118 or trash line 120. FIGS. 5A and 5B show cross sectional views of the valve apparatus at a 1/26 turn of the cylinder from each other. At each 1/26 turn the alignment of silicon line 106 and carbon line 108 switches from trash line 120 to process line or vice versa. FIG. 5A shows the silicon line 106 aligned with process line 118 and carbon line 108 aligned with trash line 120. FIG. 5B, depicting a 1/26 turn of cylinder 110 from FIG. 5A, shows silicon line 106 aligned with trash line 120 and carbon line 108 aligned with process line 118. In this manner when a gas is not being pulsed into the process line, the build up that would normally occur can be released into the trash line, thereby reducing or eliminating a burst upon a later release to the process line. Gas line and exit line configurations can be created to carry out this process for various sequences of gas pulsing.

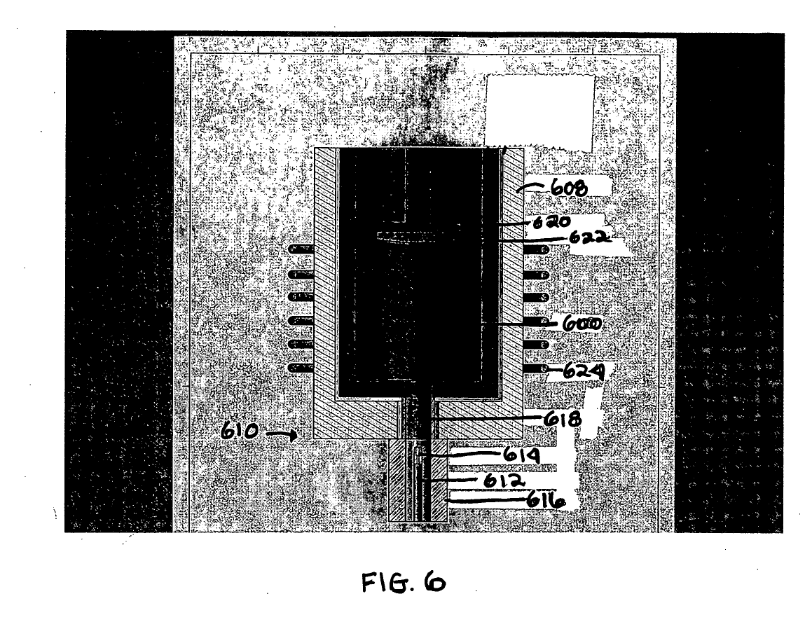

FIG. 6 depicts a cross section of a crucible and injector according to an illustrative embodiment of the invention. Crucible 600 is surrounded by insulation 608 to reduce heat loss from the crucible, which is kept at relatively high temperatures, typically in the 2000° C. range. An injector section 610 includes, at least in part, a run line 612, a nozzle 614, a water-cooled flange 616, and a thin walled graphite section 618. These components will be described in more detail below.

Process gases, such as the silicon or carbon sources, pass through run line 612 for entry into crucible 600. Nozzle 614 can direct and regulate the gas flow into crucible 600. This section of the apparatus can become extremely hot due to its proximity to the crucible. Therefore, water-cooled flange 616 is included to reduce the temperature of the run line and nozzle areas. Water-cooled flange 616, inhibits source gases from decomposing prematurely and blocking run line 612 and nozzle 614. Thin walled graphite section 618 helps to balance the thermal gradient between crucible 600 and run line 612. Other cooling and thermal gradient balancing components can be used in accordance with embodiments of the invention.

Seed holder 620 provides a surface upon which a silicon carbide crystal can be formed. Boule 622 is shown formed on seed holder 620.

Also shown in FIG. 6 is coil 624 for heating crucible 600.

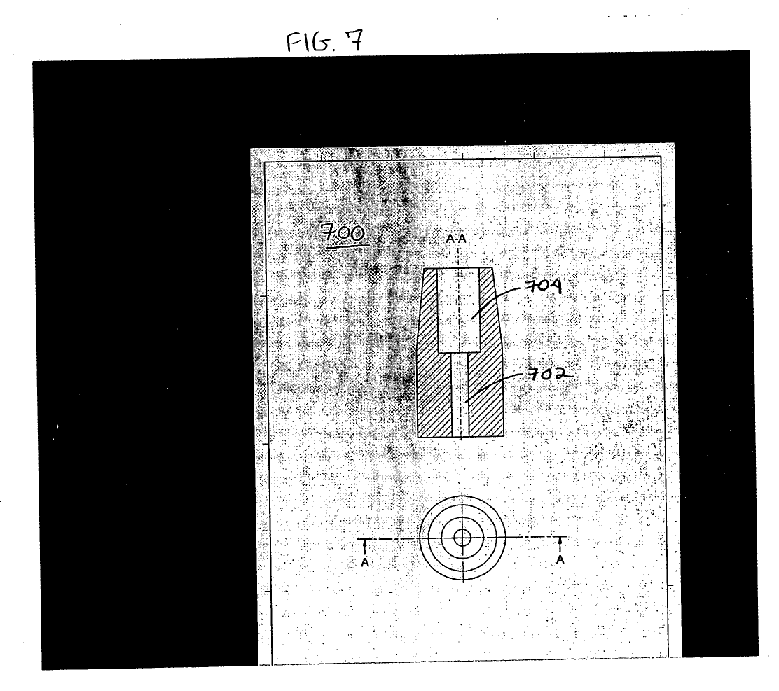

FIG. 7 depicts a cross section of a nozzle 700 according to an illustrative embodiment of the invention. Nozzle 700 controls the flow of the gases into the crucible. Exemplary nozzle 700 consists of a lower section 702 and a larger diameter upper section 704. Gases exiting lower section 702 will tend create a spray with an increasing diameter. Upper section 704 will reduce the spraying effect and create a more directional flow. This can affect the speed of injection and therefore, the position within the crucible where the gases will mix.

Embodiments of the present invention have an advantage over PCS methods in that entry of the silicon and carbon precursors can be through the same injector so there is only one opening in the reactor. With only one opening, less heat is lost as compared to the separate openings using for silicon and carbon in the PCS technique. A single opening also simplifies the apparatus from an engineering or manufacturing standpoint.

Ideally, the seed should be placed as close as possible to the presursor mixing zone so that the material may condense directly on the seed surface. The supersaturation will be very high (depending on temperature) and the urge for the species to condense will be large either to form gas phase nuclei which should be avoided or to grow on the surface.

The seed temperature will preferably be in the range of about 1700° C. to about 2500°, more preferably in the range of about 1800° C. to about 2400° C., and most preferably in the range of about 1900° C. and about 2300° C. Generally it is desirable for the temperature of the surface of the growing crystal to be about equal or lower than the temperature required to condense most products formed in the sublimation zone.

A thermal gradient between the seed and the sublimation zone may be used to facilitate transport from the formed SiC to the seed. The difference between the seed temperature and the hottest part of the sublimation zone is preferably about 1° C. and about 700° C., more preferably between about 5° C. and about 600° C., and most preferably between about 10° C. and about 500° C.

Lower pressure can also facilitate or enhance the material transport, however the pressure is usually kept high to reduce extensive evaporation from the surface of the growing crystal. The optimum pressure has been found to be 300 torr. Illustrative pressures ranges include about 1 torr to about 760 torr; and about 3 torr to about 400 torr.

A high carrier gas flow also helps transport sublimed material to the growth surface. The ideal flow rate has been found to be 4 l/min with the apparatus they use, however, the optimum rate depends on factors such as the shapes of the injector and reactor. Illustrative carrier gas flow rates include about 0.1 l/min to about 10 l/min, more preferably about 0.2 l/min to about 7 l/min, and most preferably about 0.4 l/min to about 5 l/min.

In the preferred embodiment of the invention, no gradient or a small gradient will be needed to drive the transport, which may enable very high quality material.

The pulse duration of each precursor is preferably in the range of about 0.01 ms to about 15.0 ms, more preferably in the range of about 0.05 ms to about 12.0 ms, and most preferably in the range of about 0.01 ms to about 10 ms. If pulsing is too slow, mixing will not occur in the gas phase and silicon and/or carbon will create defects in the crystal. On the other hand, if switching is too fast, large clusters may be created that are difficult to sublime.

The method can be carried out with no time gap between injections of precursors, but most apparatuses suitable for the inventive process will give rise to a time gap. An illustrative time gap between injections of precursors is in the range of about 0.01 ms to about 10 ms. Further illustrative ranges include about 0.05 ms to about 7 ms and about 0.1 ms to about 5 ms.

A purge or carrier gas may be introduced into the growth chamber during the time gap. For example, hydrogen or helium may be introduced for a duration of about 0.01 ms to about 10 ms, or for such other time gap as may be desirable to displace existing components or serve to facilitate a reaction that will take place between injected precursors.

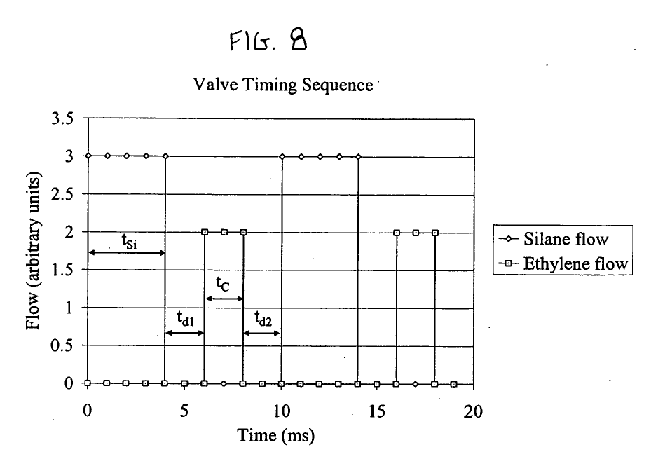

FIG. 8 shows a valve timing sequence according to an illustrative embodiment of the invention. The silicon precursor is injected into the reactor for 4 ms, designated by t_{Si}. A time gap t_{d1} of 2 ms occurs before the carbon precursor enters the reaction. The carbon precursor enters the reactor for a time of 2 ms as designated by t_{C}. Another time gap t_{d2} occurs between the next cycle of precursor injection.

In an illustrative example of the invention the flow rate of the silicon precursor is in the range of about 0.05 l/min to about 3.0 l/min, more preferably in the range of about 0.1 l/min to about 2.5 l/min, and most preferably in the range of about 0.5 l/min to about 2.0 l/min.

In an illustrative example of the invention the flow rate of the carbon precursor is in the range of about 10 ml/min to about 1000 ml/min, more preferably in the range of about 50 ml/min to about 800 ml/min, and most preferably 100 ml/min to about 700 ml/min.

In an illustrative embodiment of the invention, the gas mixtures are alternatively pulsed into the chamber with a pulse duration of the pulse of approximately 10 ms, followed by a short purge of 1-3 ms before the other constituent is entered. The total cycle is thus approximately 25 ms. An illustrative range of cycle duration is 10 ms to 50 ms.

The precursors may be reacted in the presence of other gases, for example, hydrogen or inert gases such as helium or argon. Combinations of gases may also be used. The gases may be carrier gases or introduced between pulses of silicon or carbon precursors. Hydrogen has been found to be the optimal carrier gas for carbon. It has also been found that lesser amounts of hydrogen than in HVPE can be used, which reduces or eliminates unwanted etching.

Preferably the silicon precursor is silane, however other silicon-containing compounds may be suitable, including those with elements in addition to silicon and hydrogen. Combinations of two or more silicon precursors may also be used. If silane is used, the silane will naturally go through a cluster phase where it will form droplets of silicon that will quickly evaporate. Carbon may show similar clustering depending on the thermal conditions when the chlorocarbon or hydrocarbon decomposes.

Preferably the carbon precursor is ethylene. Examples of other carbon precursors include hydrocarbons such as acetylene and methane or hydrocarbons containing additional elements, such as a halide. Combinations of two or more carbon precursors may also be used.

Preferably, the bulk growth is made on a 2-3 degree off cut substrate, however, on-axis growth or other degrees off-axis are within the spirit and scope of the invention.

The preferred parameters, for example for temperature, flow rate, pulse and gap durations and pressure provided herein are those for the formation of silicon carbide. For growth of other crystal types the preferred parameters may differ.

The invention further includes a crystal formed according to the methods described herein, and a semiconductor device having such a crystal. The semiconductor device may be or include for example, a complimentary metal oxide semiconductor (CMOS) device, micro-electro-mechanical (MEM) device, field effect transistor (FET), bipolar junction transistor (BJT), insulated gate bipolar transistor (IGBT), gate turn-off thyristor (GTO), or Schottky diode.

While the invention has been described by illustrative embodiments, additional advantages and modifications will occur to those skilled in the art. Therefore, the invention in its broader aspects is not limited to specific details shown and described herein. Modifications, for example, to the types of silicon sources and hydrocarbons, process parameters, types of crystals formed and crystal growth equipment, may be made without departing from the spirit and scope of the invention. Accordingly, it is intended that the invention not be limited to the specific illustrative embodiments, but be interpreted within the full spirit and scope of the appended claims and their equivalents.

Claimed is:

1. A method of silicon carbide growth comprising:
alternating pulses of a silicon precursor and a carbon precursor into a reaction chamber wherein each precursor is preheated in the reaction chamber before the next pulsed precursor;
reacting substantially all of at least one precursor in the gas phase to form silicon carbide prior to reaching a growth surface;
subliming the formed silicon carbide; and
condensing substantially all of the formed silicon carbide on a growth surface.

2. The method of claim 1 wherein the silicon precursor and carbon precursor react before reaching the hot zone.

3. The method of claim 1 wherein the silicon precursor and the carbon precursor react in an area of the reaction chamber having a temperature in the range of about 1000° to about 2500° C.

4. The method of claim 3 wherein the silicon precursor and the carbon precursor react in an area of the reaction chamber having a temperature in the range of about 2000° C. to about 2200° C.

5. The method of claim 1 further comprising reacting the silicon and carbon precursors in the presence of helium.

6. The method of claim 1 further comprising reacting the silicon and carbon precursors in the presence of hydrogen.

7. The method of claim 1 further comprising reacting the silicon and carbon precursors in the presence of argon.

8. The method of claim 1 further comprising reacting the silicon and carbon precursors in the presence of a hydrogen and helium mixture.

9. The method of claim 1 wherein one or more of the precursors are introduced into the reaction chamber in an inert carrier.

10. The method of claim 9 wherein the inert carrier is helium.

11. The method of claim 9 wherein the inert carrier is argon.

12. The method of claim 1 wherein one or more of the precursors are introduced into the reaction chamber in a hydrogen carrier.

13. The method of claim 1 wherein one or more of the precursors are introduced into the reaction chamber in a hydrogen and inert carrier mixture.

14. The method of claim 1 wherein the precursors are pulsed into the reaction chamber using a rotating valve.

15. The method of claim 1 wherein the silicon precursor is silane.

16. The method of claim 1 wherein the carbon precursor is ethylene.

17. The method of claim 1 wherein the carbon precursor is acetylene.

18. The method of claim 1 wherein the carbon precursor is methane

19. The method of claim 1 wherein the seed temperature is between about 1800° C. and about 2500° C.

20. The method of claim 1 wherein the temperature difference between the hottest part of the sublimation zone and the seed temperature is between about 10° C. and about 500° C.

21. The method of claim 20 wherein the temperature difference between the hottest part of the sublimation zone and the seed temperature is between about 1° C. and about 700° C.

22. The method of claim 1 wherein the temperature of the hottest part of the sublimation zone is in excess of the temperature required to sublime essentially all supplied silicon carbide.

23. The method of claim 1 wherein the temperature of the surface of the growing crystal is about equal or lower than the temperature required to condense most products formed in the sublimation zone.

24. A silicon carbide crystal grown according to the method of claim 1.

25. A semiconductor device comprising a silicon carbide crystal formed according to the method of claim 1.

26. A crystal growth chamber comprising:
a crucible in which a crystal is grown;
an injector section upstream from the crucible;
a rotating cylindrical valve to provide pulses of precursor gases to the injector section;
a first series of entry holes encircling the cylindrical valve at a first height in fluid connection with a gas inlet;
a second series of entry holes encircling the cylindrical valve at a second height in fluid connection with a gas inlet; and
a series of exit holes encircling the cylindrical valve at a third height that periodically align with an exit port, wherein the exit holes are equal in number to the sum of the number of entry holes and the exit port is upstream from the injector section.
